(19) United States
(12) Patent Application Publication
(10) Pub. No.: US 2017/0242786 A1
(43) Pub. Date: Aug. 24, 2017

(54) MEMORY SYSTEM AND OPERATION METHOD THEREOF

(71) Applicant: SK hynix Inc., Gyeonggi-do (KR)

(72) Inventor: Dong-Jae SHIN, Gyeonggi-do (KR)

(21) Appl. No.: 15/234,942

(22) Filed: Aug. 11, 2016

(30) Foreign Application Priority Data
Feb. 22, 2016 (KR) 10-2016-0020551

(51) Int. Cl. G06F 12/02; G11C 29/52; H03M 13/13; G06F 3/06; G06F 11/10

(52) U.S. Cl. CPC G06F 12/0246; G06F 3/061; G06F 3/064; G06F 3/0652; G06F 3/0665; G06F 3/0679; G06F 11/1068; H03M 13/13; G11C 29/52

(57) ABSTRACT

A memory system includes a memory device including a plurality of memory blocks and a controller suitable for selecting first memory blocks, the number of valid pages of which is equal to or less than a first threshold value, among the plurality of memory blocks, and performing a garbage collection operation on the first memory blocks based on error bit information of the first memory blocks.

### CROSS-REFERENCE TO RELATED APPLICATION

This application claims priority under 35 U.S.C. §119(a) to Korean Patent Application No. 10-2016-0020551 filed on Feb. 22, 2016 in the Korean Intellectual Property Office, the disclosure of which is incorporated herein by reference in its entirety.

### TECHNICAL FIELD

This patent document relates generally to a memory system, and more particularly, to a memory system and an operation method thereof which perform a garbage collection operation.

### SUMMARY

The disclosed technology in this patent document is directed to a memory system and an operation method of the memory system which perform a garbage collection operation based on error bit information.

In an embodiment, a memory system may include: a memory device including a plurality of memory blocks; and a controller suitable for selecting first memory blocks, the number of valid pages of which is equal to or less than a first threshold value, among the plurality of memory blocks, and performing a garbage collection operation on the first memory blocks based on error bit information of the first memory blocks.

In another embodiment, an operating method of a memory system may include: selecting first memory blocks, the number of valid pages of which is equal to or less than a first threshold value, among a plurality of memory blocks; and performing a garbage collection operation on the first memory blocks based on error bit Information of the first memory blocks.

In another embodiment, a memory system may include: a memory device Including a plurality of memory blocks; and a controller suitable for selecting at least one first memory block from among the plurality of memory blocks based on garbage collection information and error data information and performing a garbage collection operation on the selected first memory block

According to the present technology, the memory device may preferentially sort and arrange an area of which a characteristic is deteriorated when ensuring a storage area by arranging invalid data. Accordingly, the storage area of the memory device may be ensured and an error which is generated in a program/read operation may be prevented at the same time.

For this, an overhead of a controller which controls a memory device may be reduced by managing error bit information detected in a read operation, and an operation speed of the memory device may be increased.

### BRIEF DESCRIPTION OF THE DRAWINGS

The above and other features and advantages of the present invention will become more apparent to those skilled in the art to which the present invention belongs by describing in detail various embodiments thereof with reference to the attached drawings in which:

FIG. 1 is a diagram illustrating a data processing system including a memory system, according to an embodiment of the present invention.

FIG. 2 is a diagram illustrating a memory device including a plurality of memory blocks, according to an embodiment of the present invention.

FIG. 3 is a circuit diagram illustrating a memory block of a memory device, according to an embodiment of the present invention.

FIGS. 4, 5, 6, 7, 8, 9, 10, and 11 are diagrams schematically illustrating a memory device, according to various embodiments of the present invention.

FIG. 12 is a block diagram illustrating a memory system, according to an embodiment of the present invention.

FIG. 13 is a diagram Illustrating an operation for detecting error bit Information of the memory device in FIG. 12, according to an embodiment of the present invention.

FIG. 14 illustrates a table for storing garbage collection information and the worst error bit information, according to an embodiment of the present invention.

FIG. 15 is a flowchart of a general operation of the memory system in FIG. 12, according to an embodiment of the present invention.

### DETAILED DESCRIPTION

Various embodiments will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the present invention to those skilled in the art. Throughout the disclosure, like reference numerals refer to like parts throughout the various figures and embodiments of the present invention.

Unless otherwise defined, all terms including technical and scientific terms used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

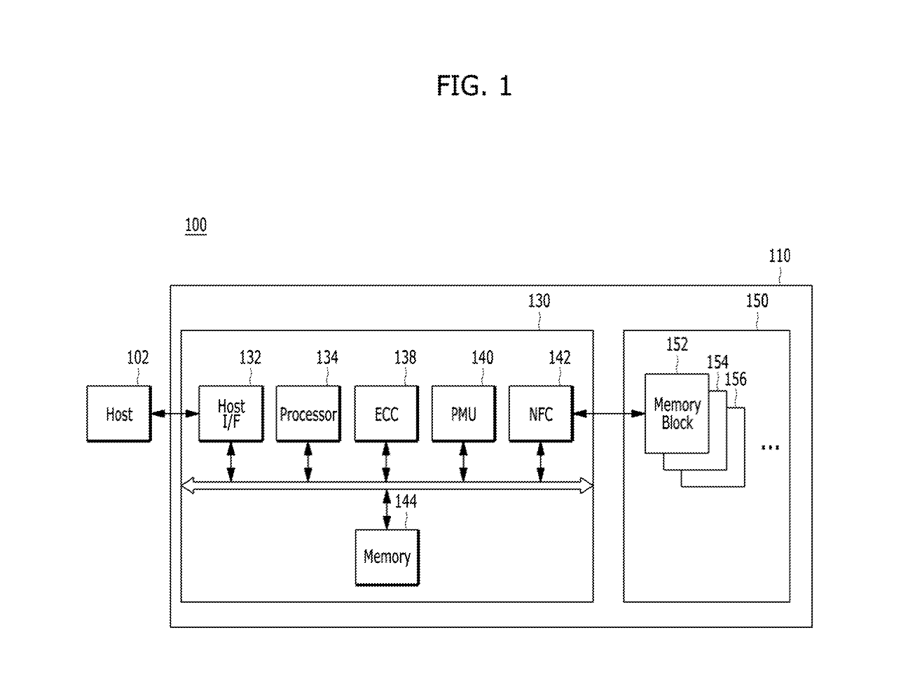

The present invention may have diverse modifications and embodiments. Also, the constituent elements of the embodiments of the present invention should be understood to not limited to the described elements only but also to include all modifications, substitutes and equivalents that are within the scope of the present invention. In this respect, the following embodiments shown in FIGS. 1 to 9 are examples which describe the present invention and should be construed not to be restrictive but to be illustrative.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention. As used herein, singular forms are intended to include the plural forms as well, unless the context clearly indicates otherwise. It will be further understood that the terms “comprises”, “comprising”, “includes”, and “including” when used in this specification, specify the presence of the stated elements and do not preclude the presence or addition of one or more other elements. As used herein, the term “and/or” includes any and all combinations of one or more of the associated listed items.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

In some instances, as would be apparent to one of ordinary skill in the art elements described in connection with a particular embodiment may be used singly or in combination with other embodiments unless otherwise specifically indicated.

Hereinafter, the various embodiments of the present invention will be described in detail with reference to the attached drawings.

FIG. 1 is a diagram illustrating a data processing system 100 including a memory system 110, according to an embodiment of the present invention.

Referring now to FIG. 1, the data processing system 100 may include a host 102 and the memory system 110.

The host 102 may include any suitable electronic device. For example, the host 102 may include a portable electronic device, such as a mobile phone, an MP3 player, a laptop computer and the like. The host 102 may include a non-portable electronic device, such as a desktop computer, a game player, a television (TV), a projector and the like.

The memory system 110 may store data to be accessed by the host 102 in response to a request from the host 102. The memory system 110 may be used as a main memory system or an auxiliary memory system of the host 102. The memory system 110 may be coupled electrically with the host 102, according to a protocol of a host interface. The memory system may include one or more semiconductor memory devices 150. Volatile or nonvolatile memory devices may be used. For example, the memory system 110 may be implemented as a solid state drive (SSD), a multimedia card (MMC), an embedded MMC (eMMC), a reduced size MMC (RS-MMC) and a micro-MMC, a secure digital (SD) card, a mini-SD and a micro-SD, a universal serial bus (USB) storage device, a universal flash storage (UFS) device, a compact flash (CF) card, a smart media (SM) card, a memory stick, and the like.

The storage devices for the memory system 110 may be implemented as a volatile memory device, such as a dynamic random access memory (DRAM), a static random access memory (SRAM) and the like. Alternatively, the storage devices for the memory system 110 may be implemented as a nonvolatile memory device, such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), a resistive RAM (RRAM) and the like.

The memory system 110 may include a memory device 150 for storing data and a controller 130 for controlling storage of data in the memory device 150. The stored data in the memory device 150 may be accessed by the host 102.

The controller 130 and the memory device 150 may be integrated into a single semiconductor device. For instance, the controller 130 and the memory device 150 may be integrated into a semiconductor device configured as a solid state drive (SSD). Configuring the memory system 110 as a SSD, may generally allow a significant increase in an operation speed of the host 102.

The controller 130 and the memory device 150 may be integrated into a semiconductor device configured as a memory card, such as a Personal Computer Memory Card International Association (PCMCIA) card, a compact flash (CF) card, a smart media (SM) card (SMC), a memory stick, a multimedia card (MMC), an RS-MMC and a micro-MMC, a secure digital (SD) card, a mini-SD, a micro-SD and an SDHC, a universal flash storage (UFS) device and the like.

Also, the memory system 110 may be or comprise a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, an RFID device, one of various component elements configuring a computing system and the like.

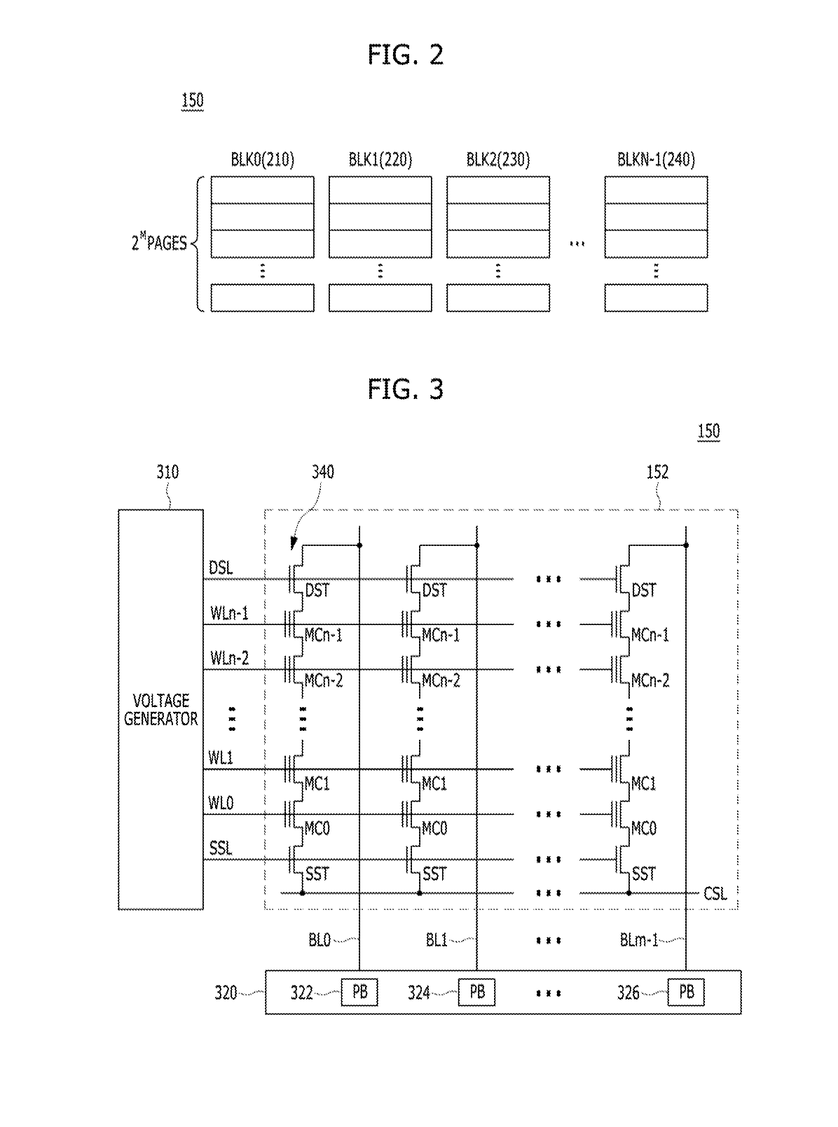

The memory device 150 may store data provided from the host 102. During a read operation, the memory device 150 may provide the stored data to the host 102. One or more memory devices 150 may be employed. The one or more memory devices 150 may be substantially Identical. The one or more memory devices may be different memory devices. The memory device 150 may include one or more memory blocks 152, 154 and 156. Each of the memory blocks 152, 154 and 156 may include a plurality of pages. Each of the pages may include a plurality of memory cells coupled electrically to one or more word lines (WL). The memory device 150 may be a nonvolatile memory device capable of retaining stored data even when a power supply is interrupted or turned off. According to an embodiment, the memory device may be a flash memory. The memory device may be a flash memory device having a three-dimensional (3D) stack structure. Examples of a nonvolatile memory device 150 having a three-dimensional (3D) stack structure are described later herein with reference to FIGS. 2 to 11.

The controller 130 may control the operations of the memory device 150, such as read, write, program and/or erase operations. Generally, the controller 130 may control the memory device 150 in response to a request from the host 102. For example, the controller 130 may provide data read from the memory device 150, to the host 102, in response to a read request from the host 102. Also, the controller 130 may store data provided from the host 102 into the memory device 150 in response to a write request.

Any suitable controller may be used. For example, the controller 130 may include a host interface unit 132, a processor 134, an error correction code (ECC) unit 138, a power management unit (PMU) 140, a NAND flash controller (NFC) 142, and a memory 144.

The host interface unit 132 may process commands and/or data provided from the host 102. The host interface unit 132 may communicate with the host 102 through at least one of various interface protocols, such as a universal serial bus (USB), a multimedia card (MMC), a peripheral component interconnect-express (PCI-E), a serial attached SCSI (SAS), a serial advanced technology attachment (SATA), a parallel advanced technology attachment (PATA), a small computer system interface (SCSI), an enhanced small disk interface (ESDI), integrated drive electronics (IDE) and the like. The host interface unit 132 may include any suitable circuits, systems or devices suitable for communicating with the host 102 and the other components of the controller 130 as may be needed.

The ECC unit 138 may detect and correct errors of the data read from the memory device 150 during a read operation. Various error detection and correction techniques may be employed. For example, if the number of the error bits detected by the ECC unit 138 is greater than or equal to a threshold number of correctable error bits, the ECC unit 138 may not correct the error bits and output an error correction fall signal indicating failure in correcting the error bits.

The ECC unit 138 may perform an error correction operation based on any suitable error correction scheme. For example, the ECC unit 138 may perform an error correction operation based on a coded modulation scheme among a plurality of well-known coded modulation schemes, such as a low density parity check (LDPC) code, a Bose-Chaudhuri-Hocquenghem (BCH) code, a turbo code, a Reed-Solomon (RS) code, a convolution code, a recursive systematic code (RSC), a Trellis-coded modulation (TCM), a block coded modulation (BCM), and the like. The ECC unit 138 may include any suitable circuits, systems or devices required for an error detection and correction operation.

The PMU 140 may provide and manage electric power for the controller 130. For example, the PMU 140 may provide and manage electric power for the various components of the controller 130 as may be needed. Any suitable power management unit may be used.

The NFC 142 is an example of a memory interface between the controller 130 and the memory device 150 to allow the controller 130 to control the memory device 150 in response to a request from the host 102, when the memory device is a NAND flash memory. For example, the NFC 142 may generate control signals for the memory device 150. The NFC may process data under the control of the processor 134. Depending on the type of the memory device 150 employed, a different memory interface may be used.

The memory 144 may serve as a working memory of the memory system 110 and the controller 130, and store data for driving the memory system 110 and the controller 130. For example, when the controller 130 controls the operations of the memory device 150, the memory 144 may store data used by the controller 130 and the memory device 150 for operations such as read, write, program and erase operations.

The memory 144 may be or comprise a volatile memory. For example, the memory 144 may be or comprise a static random access memory (SRAM) or a dynamic random access memory (DRAM). As described above, the memory 144 may store data used by the host 102 and the memory device 150 for read and/or write operations. The memory 144 may be or comprise a program memory, a data memory, a write buffer, a read buffer, a map buffer, and the like.

The processor 134 may control the operations of the memory system 110. For example, the processor 134 may control a write operation for the memory device 150, in response to a write request from the host 102. Also, the processor 134 may control a read operation for the memory device 150, in response to a read request from the host 102. The processor 134 may drive a firmware, also referred to as a flash translation layer (FTL), for controlling the general operations of the memory system 110. The processor 134 may be implemented with a microprocessor, a central processing unit (CPU) and the like. Any suitable processor may be used.

For example, a management unit (not shown) may be included in the processor 134 for performing bad block management of the memory device 150. Accordingly, the management unit may find bad memory blocks included in the memory device 150, i.e., memory blocks which are in an unsatisfactory condition for further use, and perform a bad block management operation the bad memory blocks. For example, when a flash memory, such as a NAND flash memory is employed as the memory device 150, a program failure may occur during a write operation due to inherent characteristics of a NAND logic function. During a bad block management, the data of the program-failed memory blocks (e.g., the bad memory blocks) may be programmed into a new memory block. The bad blocks due to a program fail may seriously deteriorate the utilization efficiency of a memory device, especially one having a 3D stack structure and thus negatively affect the reliability of the memory system 110.

FIG. 2 is a diagram Illustrating a memory device 150 according to an embodiment of the present invention.

Referring to FIG. 2 the memory device 150 may include a plurality of memory blocks. For example, the memory device 150 may include zeroth to (N−1) blocks 210 to 240, where N is a positive integer. Each of the plurality of memory blocks 210 to 240 may include a plurality of pages. For example, each of the plurality of memory blocks 210 to 240 may include 2^{M} number of pages (2^{M} PAGES), where M is a positive integer. Each of the plurality of pages may include a plurality of memory cells to which one or more word lines may be coupled electrically. It is noted that any number of suitable blocks and pages per block may be employed.

The memory blocks may be single level cell (SLC) memory blocks and/or multi-level cell (MLC) memory blocks, according to the number of bits which may be stored in each memory cell. An SLC memory block may include a plurality of pages which are implemented with memory cells each of which is capable of storing 1-bit data. An MLC memory block may include a plurality of pages which are implemented with memory cells each of which is capable of storing multi-bit data (e.g., two or more-bit data). An MLC memory block including a plurality of pages which are implemented with memory cells each of which is capable of storing 3-bit data may be employed and will be referred to as a triple level cell (TLC) memory block.

Each of the plurality of memory blocks 210 to 240 may store data provided from the host 102 during a write operation. Each of the plurality of memory blocks 210 to 240 may also provide stored data to the host 102 during a read operation.

FIG. 3 is a circuit diagram illustrating a memory block in a memory device, according to an embodiment of the present invention.

Referring to FIG. 3, a memory block 152 of the memory device 150 may include a plurality of cell strings 340 coupled electrically to bit lines BL0 to BLm−1, respectively. Each cell string 340 may include at least one drain select transistor DST and at least one source select transistor SST. A plurality of memory cells or a plurality of memory cell transistors MC0 to MCn−1 may be coupled electrically in series between the select transistors DST and SST. The respective memory cells MC0 to MCn−1 may consist of multi-level cells (MLC) each of which stores data information of a plurality of bits. The memory cells MC0 to MCn−1 may have any suitable architecture.

In FIG. 3, ‘DSL’ denotes a drain select line, ‘SSL’ denotes a source select line, and ‘CSL’ denotes a common source line.

FIG. 3 shows, as an example, the memory block 152 configured by NAND flash memory cells. It is to be noted, however, that the memory block 152 is not limited to the NAND flash memory cells. For example, the memory block may be implemented, in other embodiments, with NOR flash memory cells, hybrid flash memory cells having at least two kinds of memory cells combined, or a NAND flash memory cell having a controller built in a memory chip. Also, the operational characteristics of a semiconductor device may be applied to not only a flash memory device in which a charge storing layer is configured by conductive floating gates but also to a charge trap flash (CTF) in which a charge storing layer is configured by a dielectric layer.

It is also noted that the memory device 150 is not limited to a flash memory device only. For example, the memory device 150 may be a dynamic random access memory (DRAM) or a static random access memory (SRAM) device.

A voltage generator 310 of the memory device 150 may generate voltages, such as a program voltage, a read voltage or a pass voltage, to be supplied to respective word lines according to an operation mode. The voltage generator 310 may generate voltages to be supplied to bulks (e.g., well regions) in which the memory cells are formed. The voltage generator 310 may perform a voltage generating operation under a control of a control circuit (not shown). The voltage generator 310 may generate a plurality of variable read voltages to generate a plurality of read data. The voltage generator 310 may select one of the memory blocks or sectors of a memory cell array, select one of the word lines of the selected memory block, and provide the word line voltages to the selected word line and unselected word lines, under the control of the control circuit.

A read/write circuit 320 of the memory device 150 may be controlled by the control circuit, and may serve as a sense amplifier or a write driver according to an operation mode. During a verification/normal read operation, the read/write circuit 320 may serve as a sense amplifier for reading data from the memory cell array. Also, during a program operation, the read/write circuit 320 may serve as a write driver for driving bit lines according to data to be stored in the memory cell array. The read/write circuit 320 may receive data to be written in the memory cell array, from a buffer (not shown), during the program operation, and may drive the bit lines according to the inputted data. To this end, the read/write circuit 320 may include a plurality of page buffers 322, 324 and 326 respectively corresponding to the columns (or bit lines) or pairs of the columns (or pairs of bit lines). Each of the page buffers 322, 324 and 326 may include a plurality of latches (not shown).

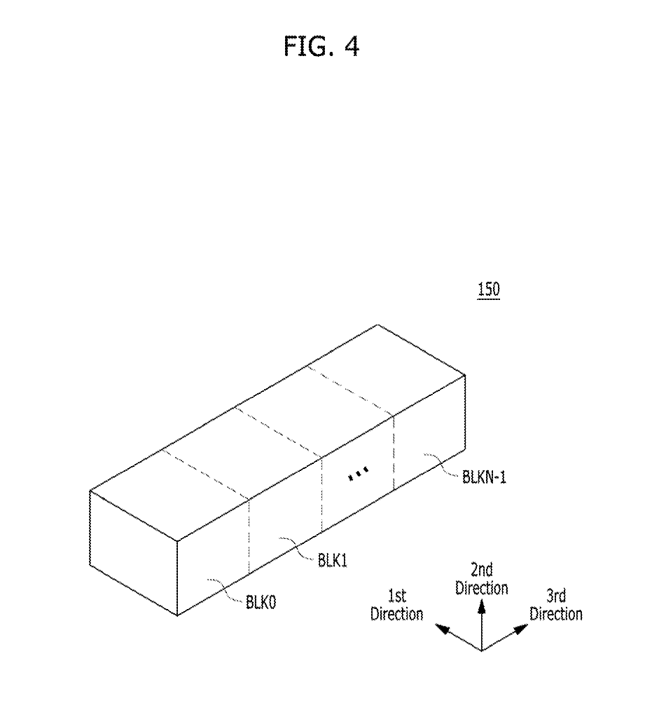

FIG. 4 is a block diagram Illustrating an example of the plurality of memory blocks included in the memory device 150, according to an embodiment of the present invention.

As shown in FIG. 4, the memory device 150 may include a plurality of memory blocks BLK0 to BLKN−1. Each of the memory blocks BLK0 to BLKN−1 may be realized in a 3D structure or a vertical structure. The respective memory blocks BLK0 to BLKN−1 may include a plurality of structures extending in first to third directions, e.g., an x-axis direction, a y-axis direction and a z-axis direction.

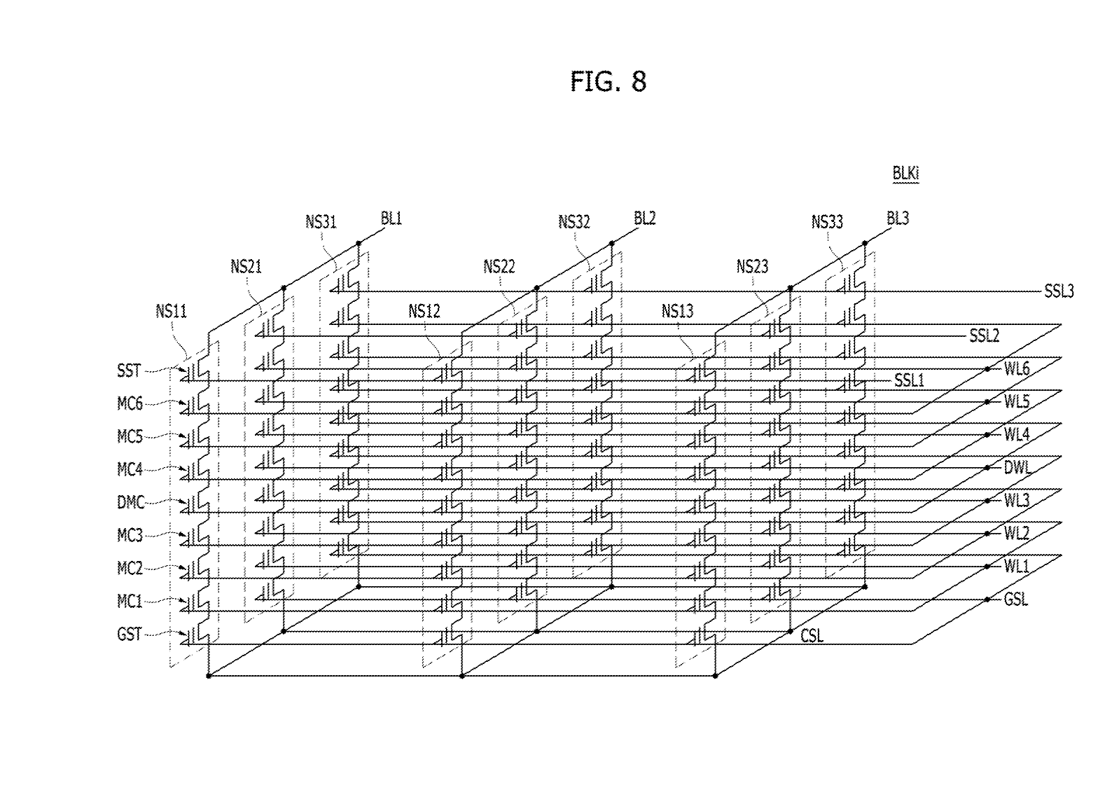

The respective memory blocks BLK0 to BLKN−1 may include a plurality of NAND strings NS extending in the second direction (FIG. 8). The plurality of NAND strings NS may be provided in the first direction and the third direction. Each NAND string NS may be coupled electrically to a bit line BL, at least one source select line SSL, at least one ground select line GSL, a plurality of word lines WL, at least one dummy word line DWL, and a common source line CSL. The respective memory blocks BLK0 to BLKN−1 may be coupled electrically to a plurality of bit lines BL, a plurality of source select lines SSL, a plurality of ground select lines GSL, a plurality of word lines WL, a plurality of dummy word lines DWL, and a plurality of common source lines CSL.

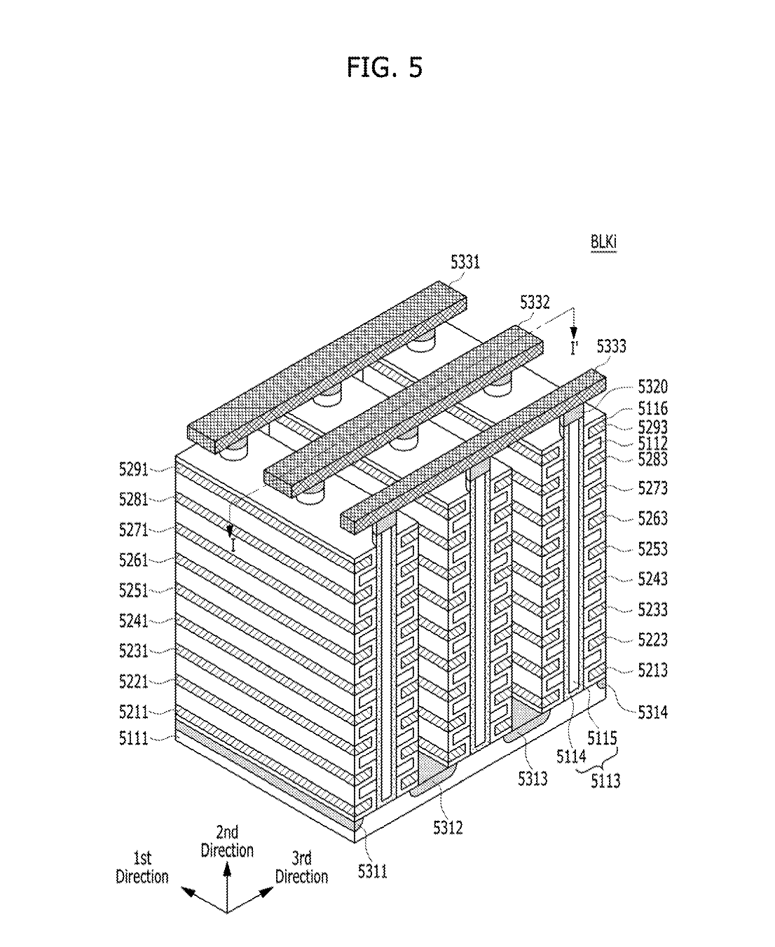

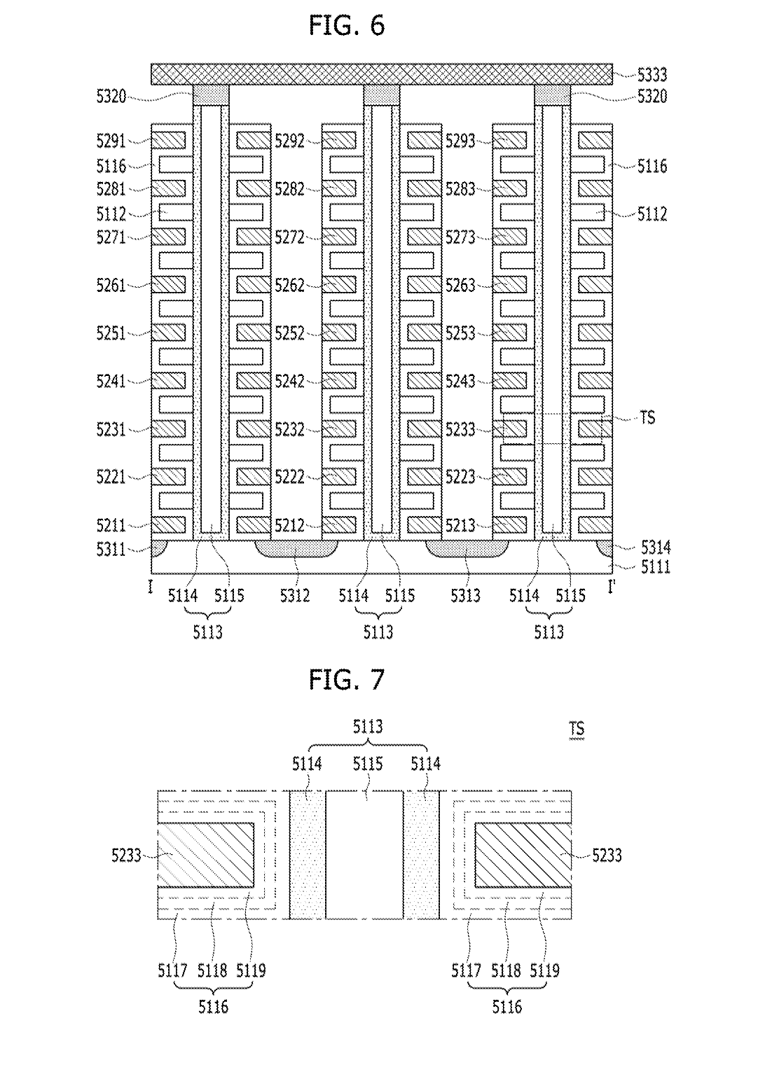

FIG. 5 is a perspective view of one memory block BLKi of the plurality memory blocks BLK0 to BLKN−1 shown in FIG. 4. FIG. 6 is a cross-sectional view taken along a line I-I′ of the memory block BLKi shown in FIG. 5.

Referring to FIGS. 5 and 6, memory block BLKi may include a structure extending in the first to third directions.

The memory block BLKi may include a substrate 5111 including a silicon material doped with a first type impurity. For example, the substrate 5111 may include a silicon material doped with a p-type impurity. The substrate 5111 may be a p-type well, for example, a pocket p-well. The substrate 5111 may further include an n-type well surrounding the p-type well. Although, in the embodiment of the present invention, the substrate 5111 is exemplified as being the p-type silicon, it is to be noted that the substrate 5111 is not limited to the p-type silicon.

A plurality of doping regions 5311 to 5314 extending in the first direction may be provided over the substrate 5111. The doping regions 5311 to 5314 are spaced apart at regular intervals in the third direction. The plurality of doping regions 5311 to 5314 may contain a second type impurity that is different from that of the impurity used in substrate 5111. For example, the plurality of doping regions 5311 to 5314 may be doped with an n-type impurity. Although, in the embodiment of the present invention, first to fourth doping regions 5311 to 5314 are exemplified as being the n-type, it is noted that they are not limited to the n-type.

In the region over the substrate 5111 between the first and second doping regions 5311 and 5312, a plurality of dielectric material regions 5112 extending in the first direction may be spaced apart at regular intervals in the second direction. The dielectric material regions 5112 may also be separated from the substrate 5111 by a preset distance in the second direction. Each of the dielectric material regions 5112 may be separated from one other by a preset distance in the second direction. The dielectric materials 5112 may include any suitable dielectric material, such as, silicon oxide.

In the regions over the substrate 5111 between two consecutive doping regions, for example, between doping regions 5311 and 5312, a plurality of pillars 5113 are spaced apart at regular Intervals in the first direction. The plurality of pillars 5113 extend in the second direction and may pass through the dielectric material regions 5112 so that they may be coupled electrically with the substrate 5111. Each pillar 5113 may include one or more materials. For example, each pillar 5113 may include an in inner layer 5115 and an outer surface layer 5114. The surface layer 5114 may include a doped silicon material doped with an impurity. For example, the surface layer 5114 may include a silicon material doped with the same or same type impurity as the substrate 5111. Although, in the embodiment of the present invention, the surface layer 5114 is exemplified as including p-type silicon, the surface layer 5114 is not limited to the p-type silicon and other embodiments may readily envisaged by the skilled person wherein the substrate 5111 and the surface layer 5114 of the pillars 5113 may be doped with an n-type impurity.

The inner layer 5115 of each pillar 5113 may be formed of a dielectric material. The inner layer 5115 may be or include a dielectric material such as silicon oxide.

In the regions between the first and second doping regions 5311 and 5312, a dielectric layer 5116 may be provided along exposed surfaces of the dielectric material regions 5112, the pillars 5113 and the substrate 5111. A thickness of the dielectric layer 5116 may be less than one half of the distance between the dielectric material regions 5112. In other words, a region of a material other than the dielectric material 5112 and the dielectric layer 5116 may be provided between (i) the dielectric layer 5116 below the bottom surface of a first dielectric material of the dielectric material regions 5112 and (ii) the dielectric layer 5116 provided over the top surface of a second dielectric material of the dielectric material regions 5112. The dielectric material regions 5112 may lie below the first dielectric material.

In the regions between consecutive doping regions such as in the region between the first and second doping regions 5311 and 5312, a plurality of conductive material regions 5211 to 5291 may be provided over an exposed surface of the dielectric layer 5116. The plurality of the conductive material regions extending in the first direction may be spaced apart at regular intervals in the second direction in an interleaving configuration with the plurality of the dielectric material regions 5112. The dielectric layers 5116 fill the space between the conductive material regions and the dielectric material regions 5112. So for example, the conductive material region 5211 extending in the first direction may be provided between the dielectric material region 5112 adjacent to the substrate 5111 and the substrate 5111. In particular, the conductive material region 5211 extending in the first direction may be provided between (i) the dielectric layer 5116 disposed over the substrate 5111 and (ii) the dielectric layer 5116 disposed below the bottom surface of the dielectric material region 5112 adjacent to the substrate 5111.

Each of the conductive material regions 5211 to 5291 extending in the first direction may be provided between (i) a dielectric layer 5116 disposed over the top surface of one of the dielectric material regions 5112 and (ii) the dielectric layer 5116 disposed below the bottom surface of the next dielectric material region 5112. The conductive material regions 5221 to 5281 extending in the first direction may be provided between the dielectric material regions 5112. The top conductive material region 5291 extending in the first direction may be provided over the uppermost dielectric material 5112. The conductive material regions 5211 to 5291 extending in the first direction may be made of or include a metallic material. The conductive material regions 5211 to 5291 extending in the first direction may be made of or include a conductive material such as polysilicon.

In the region between the second doping region 5312 and third doping region 5313, the same structures as the structures between the first and second doping regions 5311 and 5312 may be provided. For example, in the region between the second and third doping regions 5312 and 5313, the plurality of dielectric material regions 5112 extending in the first direction, the plurality of pillars 5113 which are sequentially arranged in the first direction and pass through the plurality of dielectric material regions 5112 in the second direction, the dielectric layer 5116 which is provided over the exposed surfaces of the plurality of dielectric material regions 5112 and the plurality of pillars 5113, and the plurality of conductive material regions 5212 to 5292 extending in the first direction may be provided.

In the region between the third doping region 5313 and a fourth doping region 5314, the same structures as between the first and second doping regions 5311 and 5312 may be provided. For example, in the region between the third and fourth doping regions 5313 and 5314, the plurality of dielectric material regions 5112 extending in the first direction, the plurality of pillars 5113 which are sequentially arranged in the first direction and pass through the plurality of dielectric material regions 5112 in the second direction, the dielectric layer 5116 which is provided over the exposed surfaces of the plurality of dielectric material regions 5112 and the plurality of pillars 5113, and the plurality of conductive material regions 5213 to 5293 extending in the first direction may be provided.

Drains 5320 may be respectively provided over the plurality of pillars 5113. The drains 5320 may be made of silicon materials doped with second type impurities. The drains 5320 may be made of silicon materials doped with n-type impurities. Although for the sake of convenience of explanation, the drains 5320 are exemplified as including n-type silicon, it is noted that the drains 5320 are not limited to the n-type silicon. For example, the width of each drain 5320 may be larger than the width of each corresponding pillar 5113. Each drain 5320 may be provided in the shape of a pad over the top surface of each corresponding pillar 5113.

Conductive material regions 5331 to 5333 extending in the third direction may be provided over the drains 5320. Each of the conductive material regions 5331 to 5333 may be extendedly disposed over the drains 5320 serially arranged in the third direction with a preset separation distance to each other in the first direction. The respective conductive material regions 5331 to 5333 may be coupled electrically with the drains 5320 therebelow. The drains 5320 and the conductive material regions 5331 to 5333 extending in the third direction may be coupled electrically with through contact plugs. The conductive material regions 5331 to 5333 extending in the third direction may be made of a metallic material. The conductive material regions 5331 to 5333 extending in the third direction may be made of a conductive material such as polysilicon.

In FIGS. 5 and 6, the respective pillars 5113 may form strings together with the dielectric layer 5116 and the conductive material regions 5211 to 5291, 5212 to 5292 and 5213 to 5293 extending in the first direction. The respective pillars 5113 may form NAND strings NS together with the dielectric layer 5116 and the conductive material regions 5211 to 5291, 5212 to 5292 and 5213 to 5293 extending in the first direction. Each NAND string NS may include a plurality of transistor structures TS.

Referring now to FIG. 7, in the transistor structure TS shown in FIG. 6, the dielectric layer 5116 may include first to third sub dielectric layers 5117, 5118 and 5119.

The surface layer 5114 of p-type silicon in each of the pillars 5113 may serve as a body. The first sub dielectric layer 5117 adjacent to the pillar 5113 may serve as a tunneling dielectric layer, and may include a thermal oxidation layer.

The second sub dielectric layer 5118 may serve as a charge storing layer. The second sub dielectric layer 5118 may serve as a charge capturing layer, and may include a nitride layer or a metal oxide layer, such as an aluminum oxide layer, a hafnium oxide layer, or the like.

The third sub dielectric layer 5119 adjacent to the conductive material 5233 may serve as a blocking dielectric layer. The third sub dielectric layer 5119 adjacent to the conductive material 5233 extending in the first direction may be formed as a single layer or multiple layers. The third sub dielectric layer 5119 may be a high-k dielectric layer such as an aluminum oxide layer, a hafnium oxide layer, or the like, which has a dielectric constant greater than the first and second sub dielectric layers 5117 and 5118.

The conductive material 5233 may serve as a gate or a control gate. For example, the gate or the control gate 5233, the blocking dielectric layer 5119, the charge storing layer 5118, the tunneling dielectric layer 5117 and the body 5114 may form a transistor or a memory cell transistor structure. For example, the first to third sub dielectric layers 5117 to 5119 may form an oxide-nitride-oxide (ONO) structure. In the embodiment, for the sake of convenience of explanation, the surface layer 5114 of p-type silicon in each of the pillars 5113 will be referred to as a body in the second direction.

The memory block BLKi may include the plurality of pillars 5113. For example, the memory block BLKi may include the plurality of NAND strings NS. In detail, the memory block BLKi may include the plurality of NAND strings NS extending in the second direction or a direction perpendicular to the substrate 5111.

Each NAND string NS may include the plurality of transistor structures TS which are disposed in the second direction. At least one of the plurality of transistor structures TS of each NAND string NS may serve as a string source transistor SST. At least one of the plurality of transistor structures TS of each NAND string NS may serve as a ground select transistor GST.

The gates or control gates may correspond to the conductive material regions 5211 to 5291, 5212 to 5292 and 5213 to 5293 extending in the first direction. For example, the gates or the control gates may extend in the first direction and form word lines and at least two select lines including at least one source select line SSL and at least one ground select line GSL.

The conductive material regions 5331 to 5333 extending in the third direction may be coupled electrically to one end of the NAND strings NS. The conductive material regions 5331 to 5333 extending in the third direction may serve as bit lines BL. For example, in one memory block BLKi, the plurality of NAND strings NS may be coupled electrically to one-bit line BL.

The second type doping regions 5311 to 5314 extending in the first direction may be provided to the other ends of the NAND strings NS. The second type doping regions 5311 to 5314 extending in the first direction may serve as common source lines CSL.

For example, the memory block BLKi may include a plurality of NAND strings NS extending in a direction perpendicular to the substrate 5111, e.g., the second direction, and may serve as a NAND flash memory block, for example, of a charge capturing type memory, in which the plurality of NAND strings NS are coupled electrically to one-bit line BL.

Although it is illustrated in FIGS. 5 to 7 that the conductive material regions 5211 to 5291, 5212 to 5292 and 5213 to 5293 extending in the first direction are provided by nine (9) layers, it is noted that the conductive material regions 5211 to 5291, 5212 to 5292 and 5213 to 5293 extending in the first direction are not limited thereto. For example, conductive material regions extending in the first direction may be provided in eight (8) layers, sixteen (16) layers or any multiple layers. For example, in one NAND string NS, the number of transistors may be 8, 16 or more.

Although it is illustrated in FIGS. 5 to 7 that three (3) NAND strings NS are coupled electrically to one-bit line BL, it is noted that the embodiment is not limited thereto. In the memory block BLKi, m NAND strings NS may be coupled electrically to one-bit line BL, m being a positive integer. The number of conductive material regions 5211 to 5291, 5212 to 5292 and 5213 to 5293 extending in the first direction and the number of common source lines 5311 to 5314 may be varied with the number of NAND strings NS which are coupled electrically to one-bit line BL.

Further, although it is illustrated in FIGS. 5 to 7 that three (3) NAND strings NS are coupled electrically to one conductive material extending in the first direction, it is noted that the embodiment is not limited thereto. For example, n NAND strings NS may be coupled electrically to one conductive material extending in the first direction, n being a positive integer. The number of bit lines 5331 to 5333 may be varied with the number of NAND strings NS which are coupled electrically to one conductive material extending in the first direction.

Referring to FIG. 8, in a block BLKi having the first structure, a plurality of NAND strings NS11 to NS31 may be provided between a first bit line BL1 and a common source line CSL. The first bit line BL1 may correspond to the conductive material region 5331 of FIGS. 5 and 6, extending in the third direction. NAND strings NS12 to NS32 may be provided between a second bit line BL2 and the common source line CSL. The second bit line BL2 may correspond to the conductive material region 5332 of FIGS. 5 and 6, extending in the third direction. NAND strings NS13 to NS33 may be provided between a third bit line BL3 and the common source line CSL. The third bit line BL3 may correspond to the conductive material region 5333 of FIGS. 5 and 6, extending in the third direction.

A source select transistor SST of each NAND string NS may be coupled electrically to a corresponding bit line BL. A ground select transistor GST of each NAND string NS may be coupled electrically to the common source line CSL. Memory cells MC1 and MC6 may be provided between the source select transistor SST and the ground select transistor GST of each NAND string NS.

In this example, the NAND strings NS may be defined by units of rows and columns. The NAND strings NS which are coupled electrically to one-bit line may form one column. The NAND strings NS11 to NS31 which are coupled electrically to the first bit line BL1 may correspond to a first column. The NAND strings NS12 to NS32 which are coupled electrically to the second bit line BL2 may correspond to a second column. The NAND strings NS13 to NS33 which are coupled electrically to the third bit line BL3 may correspond to a third column. The NAND strings NS which are coupled electrically to one source select line SSL may form one row. The NAND strings NS11 to NS13 which are coupled electrically to a first source select line SSL1 may form a first row. The NAND strings NS21 to NS23 which are coupled electrically to a second source select line SSL2 may form a second row. The NAND strings NS31 to NS33 which are coupled electrically to a third source select line SSL3 may form a third row.

In each NAND string NS, a height may be defined. In each NAND string NS, the height of the memory cell MC1 adjacent to the ground select transistor GST may have, for example, a value ‘1’. In each NAND string NS, the height of a memory cell may increase as the memory cell gets closer to the source select transistor SST when measured from the substrate 5111. For example, in each NAND string NS, the height of a memory cell MC6 adjacent to the source select transistor SST may have, for example, a value ‘7’.

The source select transistors SST of the NAND strings NS arranged in the same row may share the source select line SSL. The source select transistors SST of the NAND strings NS arranged in different rows may be respectively coupled electrically to the different source select lines SSL1, SSL2 and SSL3.

The memory cells at the same height in the NAND strings NS in the same row may share a word line WL. For example, at the same height, the word lines WL coupled electrically to the memory cells MC of the NAND strings NS in different rows may be coupled electrically with each other. Dummy memory cells DMC at the same height in the NAND strings NS of the same row may share a dummy word line DWL. For example, at the same height or level, the dummy word lines DWL coupled electrically to the dummy memory cells DMC of the NAND strings NS in different rows may be coupled electrically with each other.

The word lines WL or the dummy word lines DWL located at the same level or height or layer may be coupled electrically with each other for each of the layers where the conductive material regions 5211 to 5291, 5212 to 5292 and 5213 to 5293 extending in the first direction may be provided. The conductive material regions 5211 to 5291, 5212 to 5292 and 5213 to 5293 extending in the first direction may be coupled electrically in common to upper layers through contacts. In other words, the ground select transistors GST of the NAND strings NS in the same row may share the ground select line GSL. Further, the ground select transistors GST of the NAND strings NS in different rows may share the ground select line GSL. For example, the NAND strings NS11 to NS13, NS21 to NS23 and NS31 to NS33 may be coupled electrically in common to the ground select line GSL.

The common source line CSL may be coupled electrically in common to the NAND strings NS. Over the active regions over the substrate 5111, the first to fourth doping regions 5311 to 5314 may be coupled electrically. The first to fourth doping regions 5311 to 5314 may be coupled electrically in common to an upper layer through contacts.

For example, as shown in FIG. 8, the word lines WL of the same height or level may be coupled electrically to each other. Accordingly, when a word line WL at a certain height is selected, all NAND strings NS which are coupled electrically to the selected word line WL may be selected. The NAND strings NS in different rows may be coupled electrically to different source select lines SSL. Accordingly, among the NAND strings NS coupled electrically to the same word line WL, by selecting one of the source select lines SSL1 to SSL3, the NAND strings NS in the unselected rows may be electrically isolated from the bit lines BL1 to BL3. In other words, by selecting one of the source select lines SSL1 to SSL3, the NAND strings NS arranged in the same row as the selected source line may be selected. Furthermore, by selecting one of the bit lines BL1 to BL3, the NAND strings NS arranged in the same column as the selected bit line may be selected. Accordingly, only the NAND strings NS arranged in the same row as the selected source line and the same column as the selected bit line may be selected.

In each NAND string NS, a dummy memory cell DMC may be provided. In FIG. 8, for example, the dummy memory cell DMC may be provided between a third memory cell MC3 and a fourth memory cell MC4 in each NAND string NS. For example, first to third memory cells MC1 to MC3 may be provided between the dummy memory cell DMC and the ground select transistor GST. Fourth to sixth memory cells MC4 to MC6 may be provided between the dummy memory cell DMC and the source select transistor SST. The memory cells MC of each NAND string NS may be divided into two (2) memory cell groups by the dummy memory cell DMC. In the divided memory cell groups, memory cells, for example, MC1 to MC3, adjacent to the ground select transistor GST may be referred to as a lower memory cell group, and remaining memory cells, for example, MC4 to MC6, adjacent to the string select transistor SST may be referred to as an upper memory cell group.

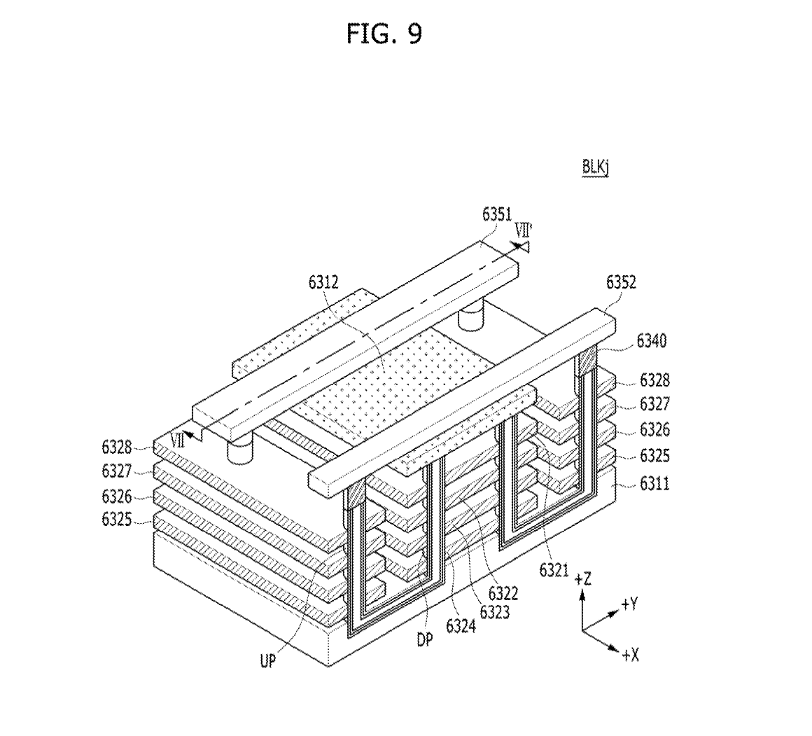

Herein below, detailed descriptions will be made with reference to FIGS. 9 to 11, which show a memory device in a memory system, according to an embodiment implemented with a three-dimensional (3D) nonvolatile memory device which is different from the first structure illustrated earlier.

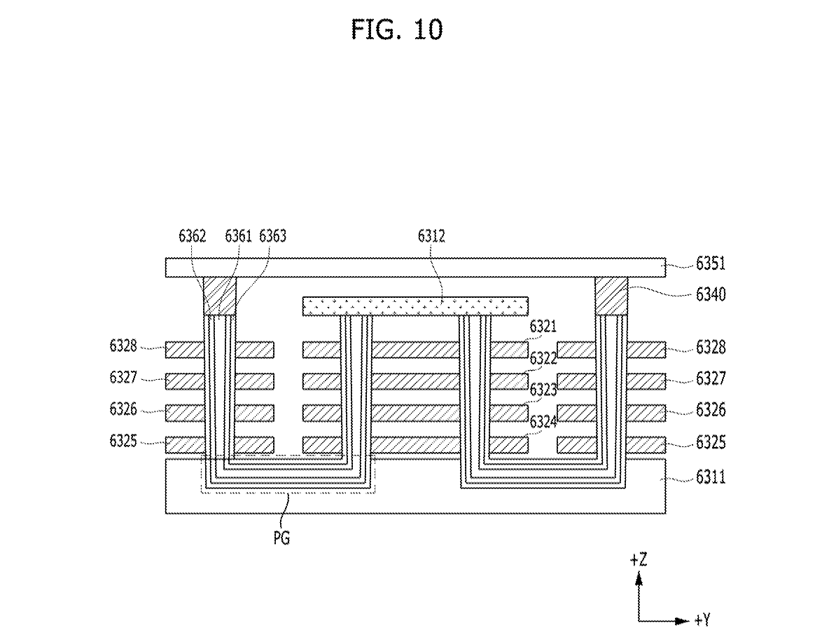

FIG. 9 is a perspective view schematically illustrating a memory device implemented with a three-dimensional (3D) nonvolatile memory device, which is different from the first structure described above with reference to FIGS. 5 to 8 and showing a memory block BLKj of the plurality of memory blocks of FIG. 4. FIG. 10 is a cross-sectional view of the memory block BLKj taken along the line VII-VII′ of FIG. 9.

Referring to FIGS. 9 and 10, the memory block BLKj may include structures extending in the first to third directions and may include a substrate 6311. The substrate 6311 may include a silicon material doped with a first type impurity. For example, the substrate 6311 may include a silicon material doped with a p-type impurity. The substrate 6311 may be a p-type well, for example, a pocket p-well. The substrate 6311 may further include an n-type well which surrounds the p-type well. Although, in the described embodiment, the substrate 6311 is exemplified as being the p-type silicon, it is noted that the substrate 6311 is not limited to the p-type silicon.

First to fourth conductive material regions 6321 to 6324 extending in an x-axis direction and a y-axis direction are provided over the substrate 6311. The first to fourth conductive material regions 6321 to 6324 may be separated by a preset distance in the z-axis direction.

Fifth to eighth conductive material regions 6325 to 6328 extending in the x-axis direction and the y-axis direction may be provided over the substrate 6311. The fifth to eighth conductive material regions 6325 to 6328 may be separated by the preset distance in the z-axis direction. The fifth to eighth conductive material regions 6325 to 6328 may be separated from the first to fourth conductive material regions 6321 to 6324 in the y-axis direction.

A plurality of lower pillars DP passing through the first to fourth conductive material regions 6321 to 6324 may be provided. Each lower pillar DP may extend in the z-axis direction. Also, a plurality of upper pillars UP passing through the fifth to eighth conductive material regions 6325 to 6328 may be provided. Each upper pillar UP may extend in the z-axis direction.

Each of the lower pillars DP and the upper pillars UP may include an internal material 6361, an intermediate layer 6362, and a surface layer 6363. The intermediate layer 6362 may serve as a channel of the cell transistor. The surface layer 6363 may include a blocking dielectric layer, a charge storing layer and a tunneling dielectric layer.

The lower and the upper pillars DP and UP may be coupled electrically with each other through a pipe gate PG. The pipe gate PG may be disposed in the substrate 6311. For example, the pipe gate PG may include the same material as the lower pillar DP and the upper pillar UP.

A doping material 6312 of a second type extending in the x-axis direction and the y-axis direction may be provided over the lower pillars DP. For example, the doping material 6312 of the second type may include an n-type silicon material. The doping material 6312 of the second type may serve as a common source line CSL.

Drains 6340 may be provided over the upper pillars UP. The drains 6340 may include an n-type silicon material. First and second upper conductive material regions 6351 and 6352 extending in the y-axis direction may be provided over the drains 6340.

The first and second upper conductive material regions 6351 and 6352 may be spaced apart along the x-axis direction. The first and second upper conductive material regions 6351 and 6352 may be formed of a metal. The first and second upper conductive material regions 6351 and 6352 and the drains 6340 may be coupled electrically with each other through contact plugs. The first and second upper conductive material regions 6351 and 6352 may serve as first and second bit lines BL1 and BL2, respectively.

The first conductive material 6321 may serve as a source select line SSL. The second conductive material 6322 may serve as a first dummy word line DWL1. The third and fourth conductive material regions 6323 and 6324 may serve as first and second main word lines MWL1 and MWL2, respectively. The fifth and sixth conductive material regions 6325 and 6326 may serve as third and fourth main word lines MWL3 and MWL4, respectively. The seventh conductive material 6327 may serve as a second dummy word line DWL2. The eighth conductive material 6328 may serve as a drain select line DSL.

The lower pillar DP and the first to fourth conductive material regions 6321 to 6324 adjacent to the lower pillar DP may form a lower string. The upper pillar UP and the fifth to eighth conductive material regions 6325 to 6328 adjacent to the upper pillar UP may form an upper string. The lower string and the upper string may be coupled electrically with each other through the pipe gate PG. One end of the lower string may be coupled electrically to the doping material 6312 of the second type which serves as the common source line CSL. One end of the upper string may be coupled electrically to a corresponding bit line through the drain 6340. One lower string and one upper string may form one cell string which is coupled electrically between the doping material 6312 serving as the common source line CSL and a corresponding one of the upper conductive material layers 6351 and 6352 serving as the bit line BL.

For example, the lower string may include a source select transistor SST, the first dummy memory cell DMC1, and the first and second main memory cells MMC1 and MMC2. The upper string may include the third and fourth main memory cells MMC3 and MMC4, the second dummy memory cell DMC2, and a drain select transistor DST.

In FIGS. 9 and 10, the upper string and the lower string may form a NAND string NS. The NAND string NS may include a plurality of transistor structures TS. Since the transistor structure included in the NAND string NS in FIGS. 9 and 10 is described above in detail with reference to FIG. 7, a detailed description thereof will be omitted herein.

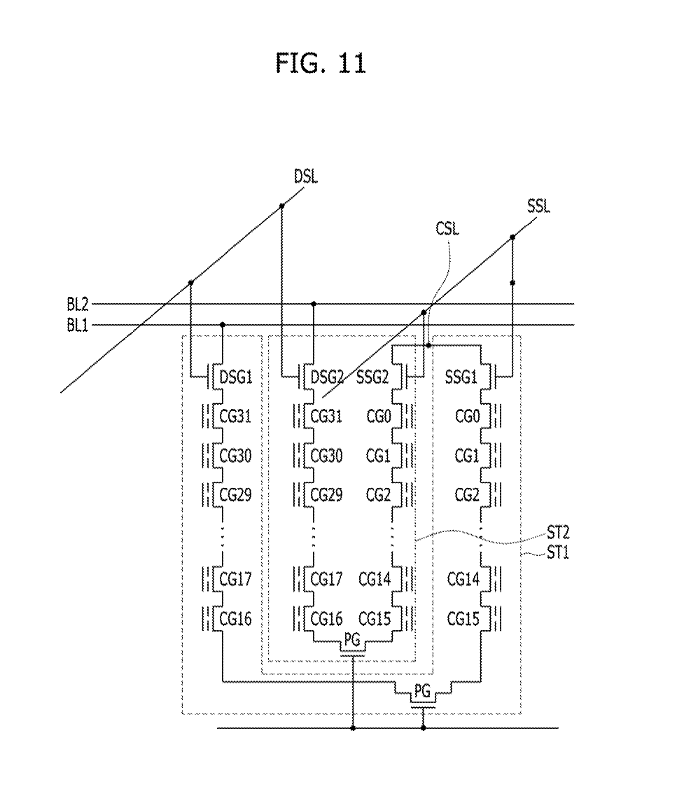

FIG. 11 is a circuit diagram Illustrating the equivalent circuit of the memory block BLKj having the second structure as described above with reference to FIGS. 9 and 10. For the sake of convenience, only a first string ST1 and a second string ST2 are shown, forming a pair in the memory block BLKj in the second structure.

Referring to FIG. 11, in the memory block BLKj having the second structure, a plurality of cell strings, each of which is implemented with one upper string and one lower string coupled electrically through the pipe gate PG as described above with reference to FIGS. 9 and 10, may be provided, in such a way as to define a plurality of pairs.

For example, in memory block BLKj having the second structure, memory cells CG0 to CG31 stacked along a first channel CH1 (not shown), for example, at least one source select gate SSG1 and at least one drain select gate DSG1 may form a first string ST1, and memory cells CG0 to CG31 stacked along a second channel CH2 (not shown), for example, at least one source select gate SSG2 and at least one drain select gate DSG2 may form a second string ST2.

The first and the second strings ST1 and ST2 may be coupled electrically to the same drain select line DSL and the same source select line SSL. The first string ST1 may be coupled electrically to a first bit line BL1. The second string ST2 may be coupled electrically to a second bit line BL2.

Although FIG. 11 shows that the first string ST1 and the second string ST2 are coupled electrically to the same drain select line DSL and the same source select line SSL, it may be envisaged that the first string ST1 and the second string ST2 may be coupled electrically to the same source select line SSL and the same bit line BL, the first string ST1 may be coupled electrically to a first drain select line DSL1, and the second string ST2 may be coupled electrically to a second drain select line DSL2. Further, it may be envisaged that the first string ST1 and the second string ST2 may be coupled electrically to the same drain select line DSL and the same bit line BL, the first string ST1 may be coupled electrically to a first source select line SSL1 and the second string ST2 may be coupled electrically a second source select line SSL2.

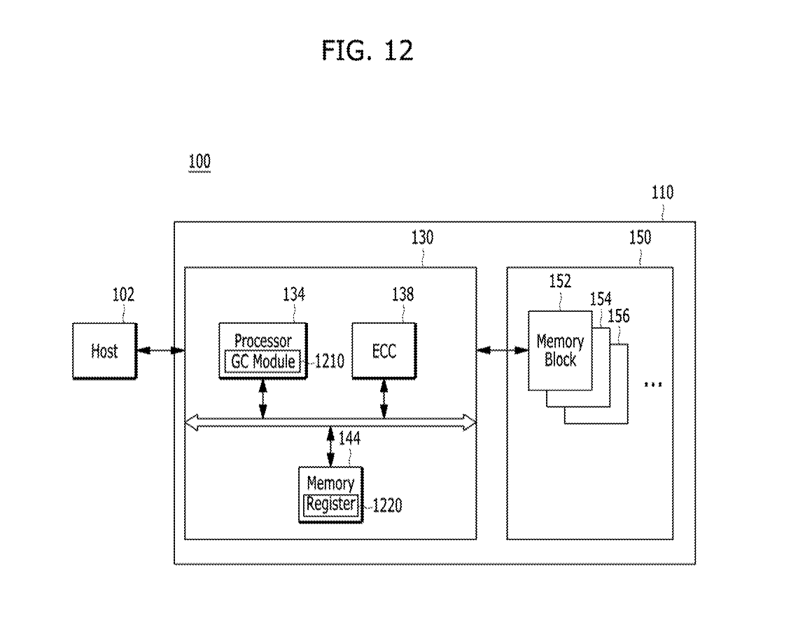

FIG. 12 is a block diagram illustrating a memory system 110 according to an embodiment of the present invention.

Referring to FIG. 12, we note that the memory system 110 included in a data processing system 100 is similar to the memory system 110 illustrated in FIG. 1. Hence, only certain of the components of the memory system 110 are illustrated in more detail in FIG. 12 to assist in the description and operation of another embodiment of the present invention.

As Illustrated in FIG. 12, the memory system 110 may include a controller 130, and a memory device 150. The controller 130 may include a processor 134, an error correction code (ECC) unit 138, and a memory 144. The memory device 150 may include a plurality of memory blocks 152, 154 and 156. The processor 134 of the controller 130 includes a garbage collection (GC) module 1210, and the memory 144 includes a register 1220. However, the present embodiment is not limited only to the illustrated configuration. For example, the garbage collection module 1210 may be configured separately from the processor 134. Also, the register 1220 may be configured separately form the memory 144.

For example, the memory device 150 may be a nonvolatile memory device. When the memory device 150 is a nonvolatile memory device, such as a flash memory, the controller 130 may perform a garbage collection operation to increase storage capacity of the memory device 150. For example, the garbage collection operation includes selecting a memory block, e.g., memory block 152 which may have invalid data of a predetermined reference or more, copying the valid data of the memory block 152 to another memory block 154 or 156, and then erasing the memory block 152 having only invalid data. Hence, following the garbage operation, the erased memory block 152, becomes a free block and a data storage area corresponding to the erased memory block 152 is obtained.

The garbage collection module 1210 may manage the garbage collection operation including collecting the valid data of a target memory block of a memory device 150 and erasing the invalid data of the target memory block. For example, the garbage collection module 1210 may manage garbage collection information including the number of valid/invalid pages of the memory blocks 152 to 156, the number of free blocks and so on. The garbage collection module 1210 may manage the garbage collection operation based on error bit information of the memory blocks 152 to 156 as will be described below in detail.

As described above, when data stored in the memory device 150 is read, the error correction code unit 138 of the controller 130 may detect and correct an error which is included in the data read from the memory device 150. However, the error correction code unit 138 may not correct an error bit when the number of error bits included in the read data is greater than or equal to a threshold value, and may manage a corresponding memory block by processing the memory block as a bad block.

Therefore, the controller 130 may perform a read reclaim operation according to whether or not the number of error bits of the data read from one memory block is greater than a reference threshold value. The data of the memory block in which the number of error bits is greater than the reference threshold value may be entirely read and copied to another memory block. Through the read reclaim operation, a disturbance may be prevented from being generated in a read operation by moving the data of memory cells of which a retention characteristic and so on are deteriorated.

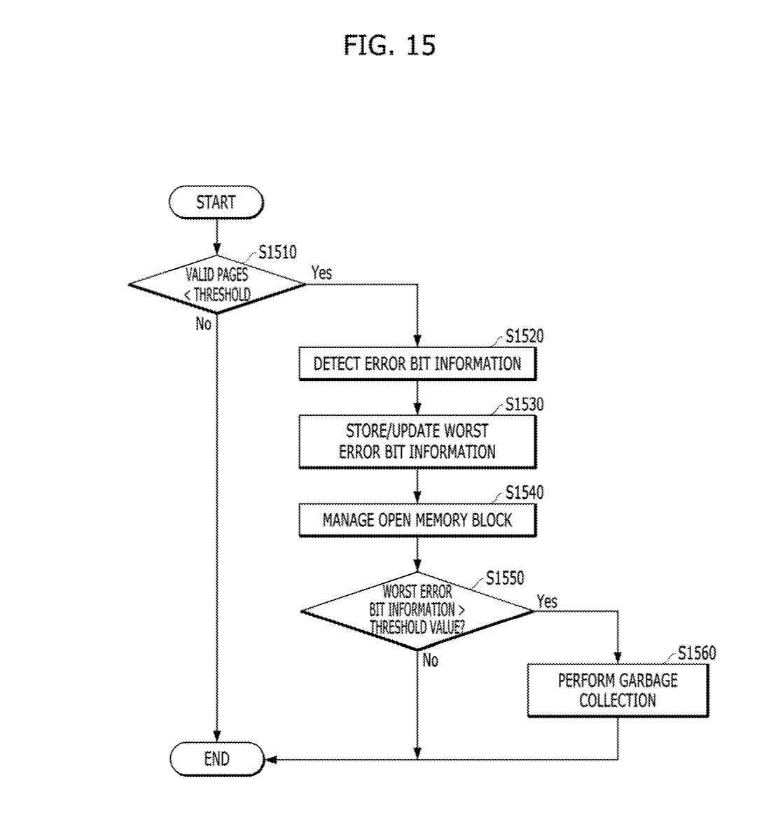

The garbage collection module 1210 may manage the error bit information by combining the error bit information with the garbage collection information. That is, while performing a garbage collection operation, which simply ensures a free area, the garbage collection module 1210 may arrange an area of which a characteristic is deteriorated for the free area. Therefore, an overhead of the controller 130 for driving the memory device 150 may be reduced, and an operation speed of the memory device 150 may be increased. A detailed operation of the memory system 110 will be described later with reference to FIG. 15.

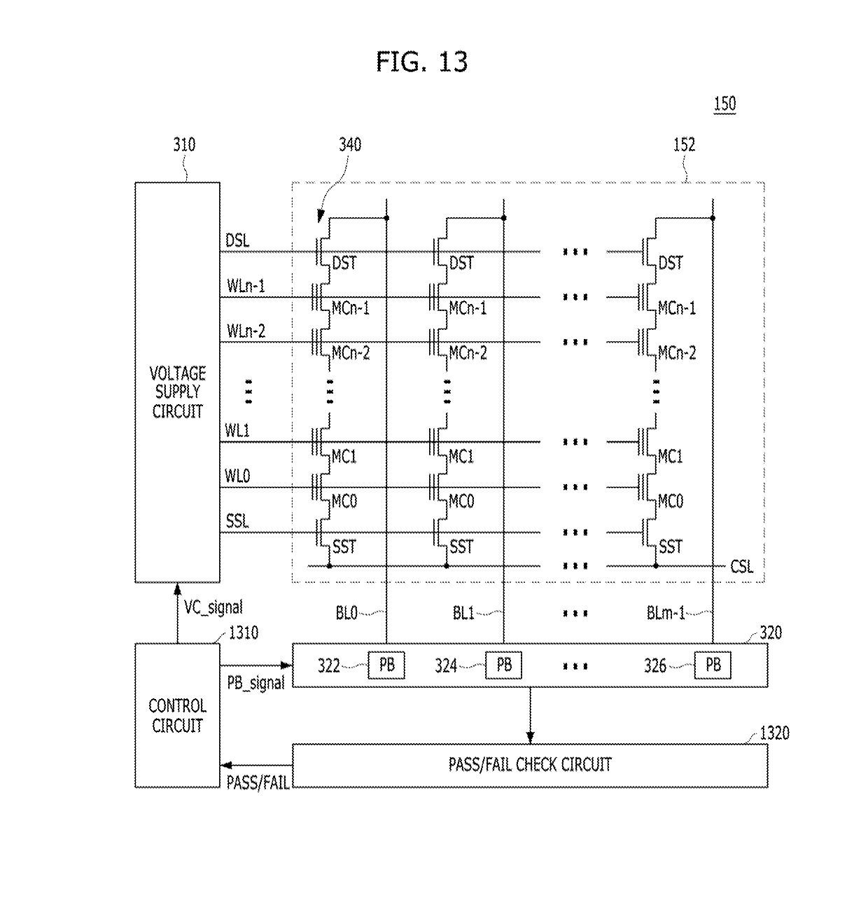

FIG. 13 is a diagram illustrating an operation which detects error bit Information of the memory device 150 in FIG. 12.

Referring to FIG. 13, it can be seen that the memory device 150 is illustrated with reference to a configuration of the memory device 150 illustrated in FIG. 3. That is, based on the configuration of the memory device 150 in FIG. 3, a control circuit 1310 and a pass/fall check circuit 1320 may be further configured according to an embodiment of the present invention.

In a read operation of the memory device 150, the control circuit 1310 may control a voltage supply circuit 310 and a read/write circuit 320 by generating a voltage control signal VC_signal and a buffer control signal PB_signal.

The voltage supply circuit 310 may generate a read voltage and a pass voltage in response to the voltage control signal VC_signal received from the control circuit 1310 in the read operation. The voltage supply circuit 310 may apply the read voltage to a selected word line WL of a block and the pass voltage to the remaining non-selected word lines WL of the block. The selected word line is selected according to a row address received from the outside and processed via a row decoder.

The read/write circuit 320 may operate as a sense amplifier in response to the buffer control signal PB_signal received from the control circuit 1310. For example, the read/write circuit 320 may read the data which is stored in memory cells MC by sensing a status of the memory cells MC coupled to the word line WL selected by the voltage supply circuit 310 through a bit line BL.

The pass/fall check circuit 1320 may detect the error bit information of the read data in units of a page buffer (PB) group which is included in the read/write circuit 320 in the read operation. The pass/fail check circuit 1320 may count an error bit by detecting the error bit based on the read data which is stored in the page buffers which is included in each page buffer group. The pass/fail check circuit 1320 may output a pass/fail signal PASS/FAIL by determining whether the number of counted error bits is greater than or less than the number of correctable permission bits in the error correction code unit 138. The pass/fail check circuit 1320 may output a pass signal PASS when the number of counted error bits is equal to or less than the number of correctable permission bits, while the pass/fall check circuit 1320 may output a fall signal FAIL when the number of counted error bits is greater than the number of correctable permission bits.

At this time, the control circuit 1310 may determine a success/fail of the read operation of the memory device 150 in response to the pass/fail signal PASS/FAIL received from the pass/fail check circuit 1320. Also, the control circuit 1310 may supply the number of error bits counted in the pass/fall check circuit 1320 to the controller 130 of FIG. 12 as the error bit information. For example, the number of counted error bits may correspond to the error bit information of one reference unit, for example, one data chunk or data of one page, for the read operation. However, the present embodiment is not limited thereto.

The garbage collection module 1210 of FIG. 12 may receive the error bit information from the memory device 150, may manage the error bit information by recording the error bit information together with the garbage collection information in the register 1220 of FIG. 12. Then, in a garbage collection operation, the garbage collection module 1210 may perform an operation which manages the garbage collection information and the error bit information, and select a target block for performing the garbage operation (hereinafter also referred to as a victim target block) among a plurality of memory blocks based on the combined garbage collection and error bit information.

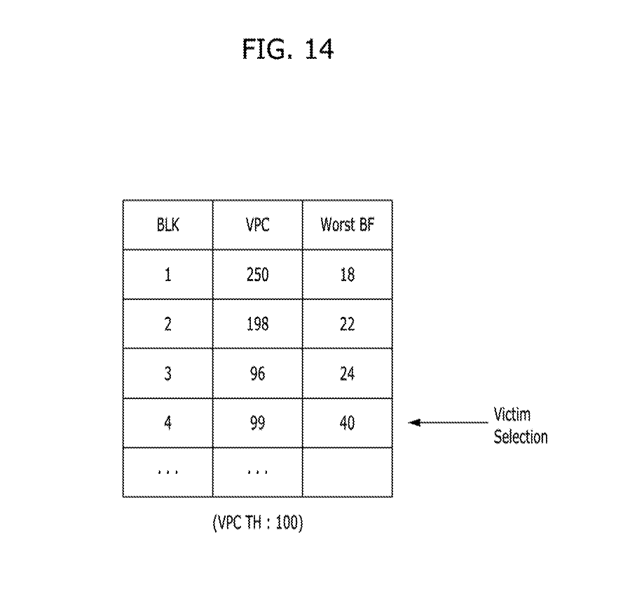

FIG. 14 illustrates an example of a table which stores garbage collection information and error bit information (i.e., the worst error bit information). The table may also be referred to hereinafter as a managed information table. In one embodiment, it is Illustrated that Information of four memory blocks BLK1 to BLK4 may be recorded in a managed information table and managed, but the present embodiment is not limited thereto.

The garbage collection information VPC stored in the managed information table may include the number of valid pages in each block of the memory device. In the example of FIG. 14, it can be seen that the first to fourth memory blocks BLK1, BLK2, BLK3 and BLK4 Include 250 valid pages, 198 valid pages, 96 valid pages, and 99 valid pages, respectively. Also, the worst error bit information Worst BF stored in the managed information table represents the number of the worst error bits which is generated in the data read in reference units.

For example, when a read (or verification) operation is performed in the first to the fourth memory blocks BLK1, BLK2, BLK3 and BLK4, the number of error bits detected from the page buffer group may be supplied as the error bit information, and the worst error bit information Worst BF may be compared with the new error bit information and be updated to the largest value of the two whenever the new error bit information is detected. Based on the information of the managed information table of FIG. 14, (which is kept in the register 1220) it can be seen that the first memory block BLK1 may ensure the biggest free area and has a better retention characteristic than the other blocks. It can also be seen that the third and the forth memory block BLK3 and BLK4 may ensure the smallest free area and have the worst retention characteristics.

If the garbage collection operation were to be performed based on only the garbage collection Information VPC, when the threshold value is set to 100, since the numbers of valid pages in the third and the forth memory blocks BLK3 and BLK4 is corresponding to 96 and 99, respectively, the third and the forth memory blocks BLK3 and BLK4 would have been selected as victim blocks. Particularly, since the free area of the third memory block BLK3 is relatively smaller as compared to the free area of the fourth memory block BK4, the garbage collection operation may be performed on the third memory block BLK3 for ensuring more free area.

However, the forth memory block BLK4 has a number of worst error bits which is greater than that of the third memory block BLK3, hence the fourth memory block BLK4 is worse than the third memory block BLK3. Therefore, to preferentially arrange the fourth memory block BLK4 may prevent the corresponding block from being processed as a bad block, and the memory blocks may be more efficiently managed. Hence, according to an embodiment of the present invention, the garbage collection operation may be performed with reference to the worst error bit Information Worst BF together with the valid page count of the garbage collection information VPC, thus ensuring that victim memory block is selected for optimizing the free data storage area created and simultaneously a memory block of which the characteristic is deteriorated may be arranged as the victim memory block.

For this, as Illustrated in FIG. 14, the garbage collection information VPC and the worst error bit information Worst BF corresponding to each memory block may be simultaneously stored and updated in a managed information table. In another embodiment, the area effectiveness of the memory 144 may be increased by storing only a portion of information. For example, the error bit information may be detected by selecting only the third and the forth memory block BLK3 and BLK4 of which the garbage collection information VPC is less than the threshold value, and updated the error bit information as the worst error bit information Worst BF. Further, the worst error bit information Worst BF may be updated by selecting only upper N (where N is a natural number) worst error bit information Worst BF among the worst error bit information Worst BF of the selected memory blocks. At this time, the selected memory blocks may be continuously changed according to the change of the garbage collection information VPC.

FIG. 15 is a flowchart illustrating a general operation of the memory system 110 in FIG. 12.

1) Valid Page Confirmation S1510

The garbage collection module 1210 of the controller 130 may manage the number of valid pages of the plurality memory blocks 152, 154 and 156 included in the memory device 150. The number of valid pages may be stored as the garbage collection information VPC. The garbage collection module 1210 may compare the valid page value of the memory blocks and a reference threshold value TH, separately select the memory blocks of which a valid page value is less than the reference threshold value TH and manage the selected memory block as a victim target block. The garbage collection module 1210 may manage by continuously updating the victim target block according to change of the number of valid pages. For the memory block having a valid page value less than the threshold value TH, further operations are performed in steps S1520 to S1560.

2) Error Bit Information Detection S1520

In the valid page confirmation step S1510, the error bit information for memory blocks which are selected as the victim target blocks may be detected. The voltage supply circuit 310 of FIG. 13 may apply a read voltage to word lines WL of the selected memory blocks according to control of the control circuit 1310, and at this time, a plurality page buffers (PB) of the read/write circuit 320 may read data in reference units. The pass/fail check circuit 1320 may detect the number of error bits which is included in the read data as the error bit information of the selected memory blocks by counting the number of error bits. The error bit information detection operation may be performed separately with the read operation respect to the selected memory blocks, or simultaneously performed in the read operation with respect to the general operation of the memory device 150.

3) Worst Error Bit Information Storage/Update S1530

Whenever the error bit information is detected in the error bit information detection step S1520, the garbage collection module 1210 may store and update the worst error bit information Worst BF in the register 1220. As described above, in the embodiment, the garbage collection module 1210 may store and update the worst error bit information Worst BF by various ways. In some embodiments, the garbage collection module 1210 may store all the error bit information of the selected memory blocks, compare the stored error bit information value of the corresponding memory block with new error bit information whenever the new error bit information is detected, and update a large value as the worst error bit information Worst BF. Alternatively, the garbage collection module 1210 may store the information (i.e., the error bit information and a block address) of the memory blocks having upper first to nth (where n is a natural number) error bit information values among the selected memory blocks, compare the stored error bit information value with new error bit information whenever the new error bit information is detected and update the information of the memory blocks having the upper the first to the nth error bit information values as the worst error bit information Worst BF again.

4) Open Memory Block Management S1540

The garbage collection module 1210 of the controller 130 may manage open memory blocks in which a data storage is not performed yet together with valid pages of the plurality of memory blocks 152, 154 and 156 included in the memory device 150. That is, the garbage collection module 1210 of the controller 130 may check the number of open memory blocks, and perform the garbage collection operation to ensure a storage area by arranging invalid pages when the number of open memory blocks is equal to or less than a predetermined value.

5) Worst Error Bit Information Confirmation S1550

In the garbage collection operation, the garbage collection module 1210 may confirm the worst error bit Information Worst BF which is stored in the register 1220. When the worst error bit information Worst BF of the selected memory blocks are entirely stored, the garbage collection module 1210 may perform the garbage collection operation S1560 on the memory block corresponding to the worst error bit information Worst BF which is greater than or equal to a preset threshold value, among the worst error bit information Worst BF. In another embodiment, when upper first to nth worst error bit information Worst BF are stored, the garbage collection module 1210 may sequentially perform the garbage collection operation S1560 on the memory blocks corresponding thereto.

In the embodiment, the memory device having a three-dimensional stack structure which is implemented in a first or a second structure is illustrated, but the present implementation is not limited thereto, and it may be applied to a memory device having a two-dimensional structure.

Although various embodiments have been described for Illustrative purposes, it will be apparent to those skilled in the art that various changes and modifications may be made without departing from the spirit and scope of the invention as defined in the following claims.

What is claimed is:

1. A memory system comprising:
a memory device Including a plurality of memory blocks; and
a controller suitable for selecting first memory blocks, the number of valid pages of which is equal to or less than a first threshold value, among the plurality of memory blocks, and
performing a garbage collection operation on the first memory blocks based on error bit information of the first memory blocks.

2. The memory system of claim 1, wherein the error bit information comprises the number of error bits which are included in data read from each reference unit of the first memory blocks.

3. The memory system of claim 2, wherein the controller is suitable for storing the error bit information of the first memory blocks, and suitable for comparing new error bit information of the first memory blocks with the stored error bit information thereof whenever the new error bit information is detected and updating the stored error bit information with a larger value between the compared information.

4. The memory system of claim 3, wherein the controller is suitable for preferentially performing the garbage collection operation on a memory block having a corresponding stored error bit information greater than or equal to a second threshold value among the first memory blocks.

5. The memory system of claim 2, wherein the controller is suitable for storing error bit information and addresses of memory blocks having upper first to nth (n is a natural number) error bit information values among the first memory blocks and suitable for comparing new error bit information of the first memory blocks with the stored error bit information whenever the new error bit information is detected and updating the stored error bit information and addressed based on a result of the comparing.

6. The memory system of claim 5, wherein the controller is suitable for preferentially performing the garbage collection operation on the memory blocks having the upper first to nth error bit information among the first memory blocks.

7. The memory system of claim 2, wherein the memory device comprises:
a read/write circuit suitable for reading data from each reference unit of a second selected memory block among the memory blocks; and
a pass/fail check circuit suitable for counting the number of error bits which is included in the read data and detecting the number of counted error bits as the error bit information of the second selected memory block.

8. The memory system of claim 7, wherein the controller comprises:
a memory suitable for storing the detected error bit Information;
a processor suitable for updating the error bit information stored in the memory based on a comparison result by comparing the detected error bit information with the error bit information stored in the memory; and
an error correction code unit suitable for correcting the error bits which is included in the read data based on the detected error bit information.

9. The memory system of claim 1, wherein the controller comprises:
a garbage collection module suitable for managing the garbage collection operation by setting the first threshold value based on the number of appropriate valid pages included in each memory block.

10. An operation method of a memory system comprising:
selecting first memory blocks, the number of valid pages of which is equal to or less than a first threshold value, among a plurality of memory blocks; and
performing a garbage collection operation on the first memory blocks based on error bit information of the first memory blocks.

11. The operation method of claim 10, wherein the error bit information comprises the number of error bits which is generated in data read from each reference unit of the first memory blocks.

12. The operation method of claim 11, further comprising: before the performing of the garbage collection operation on the first memory blocks based on the error bit information of the first memory blocks,
detecting the error bit information of the first memory blocks; and
managing the detected error bit information.

13. The operation method of claim 12, wherein the managing of the detected error bit information comprises:
storing the error bit information of the first memory blocks; and
comparing new error bit information of the first memory blocks with the stored error bit information thereof whenever the new error bit information is detected and updating the stored error bit information as a larger value between the compared information.

14. The operation method of claim 13, wherein the performing of the garbage collection operation on the first memory blocks based on the error bit information of the first memory blocks comprises preferentially performing the garbage collection operation on a memory block having a corresponding error bit information that is greater than or equal to a second threshold value among the first memory blocks.

15. The operation method of claim 12, wherein the managing of the detected error bit information comprises:
storing error bit information and addresses of memory blocks having upper first to nth (where n is a natural number) error bit Information values among the first memory blocks; and
comparing new error bit information of the first memory blocks with the stored error bit information value whenever the new error bit information is detected and updating the stored error bit information and addresses based on a result of comparing.

16. The operation method of claim 15, wherein the performing of the garbage collection operation on the first memory blocks based on the error bit information of the first memory blocks comprises preferentially performing the garbage collection operation on the memory blocks having the upper the first to the nth error bit information.

17. The operation method of claim 12, wherein the detecting of the error bit information of the first memory blocks comprises:
reading data from each reference unit of a selected memory block among the first memory blocks; and
counting the number of error bits which is included in the read data and detecting the number of counted error bits as the error bit information of the selected memory block.

18. The operation method of claim 10, further comprising
managing an open memory block in which new data is to be stored among the plurality of memory blocks,
wherein the garbage collection operation is performed when the number of open memory blocks is equal to or less than a predetermined value.

19. A memory system comprising:
a memory device including a plurality of memory blocks; and
a controller suitable for selecting at least one first memory block from among the plurality of memory blocks based on garbage collection information and error data information and performing a garbage collection operation on the selected first memory block.

20. The memory system of claim 19, wherein the garbage collection Information includes a number of valid pages for each block.
